(19) United States
(12) Patent Application Publication
(10) Pub. No.: US 2015/0188544 A1
(43) Pub. Date: Jul. 2, 2015

(54) SEMICONDUCTOR APPARATUS CROSS-REFERENCES TO RELATED APPLICATION

(71) Applicant: SK hynix Inc., Icheon-si (KR)

(72) Inventor: Eun Ho HEO, Icheon-si (KR)

(73) Assignee: SK hynix Inc., Icheon-si (KR)

(21) Appl. No.: 14/243,526

(22) Filed: Apr. 2, 2014

(30) Foreign Application Priority Data
Dec. 30, 2013 (KR) 10-2013-0167019

(51) Int. Cl. H03K 19/0185

(52) U.S. Cl. CPC H03K 19/018521

(57) ABSTRACT

A semiconductor apparatus including an inverter chain including a plurality of inverters, wherein the plurality of inverters are electrically coupled in series, and at least one of the plurality of inverters includes at least two output nodes.

### CROSS-REFERENCES TO RELATED APPLICATION

The present application claims priority under 35 U.S.C. §119(a) to Korean application number 10-2013-0167019, filed on Dec. 30, 2013, in the Korean Intellectual Property Office, which is incorporated herein by reference in its entirety.

### BACKGROUND

1. Technical Field

Various embodiments relate to a semiconductor apparatus, and more particularly, to a semiconductor apparatus including an inverter chain.

2. Related Art

Referring to FIGS. 1 and 2, a prior art inverter chain 10 may include a plurality of inverters 11, 12, 13, 14, 15.

The output terminal of each inverter in the inverter chain 10 is electrically coupled with the input terminal of a next inverter. For example, the output terminal of the first inverter 11 is electrically coupled with the input terminal of the second inverter 12. The electrical coupling of the first inverter 11 with the second inverter 12 is implemented via a single path between the midway portion of the output terminal of the first inverter 11 and the input terminal of the second inverter 12.

Each inverter includes a PMOS transistor and an NMOS transistor. The output terminal of each of the inverters 11, 12, 13, 14, 15 is disposed at a midway position on a line 20. The output terminal of each of the inverters 11, 12, 13, 14, 15 is electrically coupled to the drain terminal PD of the PMOS transistor and to the drain terminal of ND of the PMOS transistor via the line 20. The input terminal of each of the inverters 11, 12, 13, 14, 15 is disposed at a midway position on a line 30. The input terminal of each of the inverters 11, 12, 13, 14, 15 is electrically coupled a gate terminal PG of the PMOS transistor and to a gate terminal NG of the NMOS transistor.

### SUMMARY

In an embodiment, a semiconductor apparatus includes an inverter chain including a plurality of inverters, wherein the plurality of inverters are electrically coupled in series, and at least one of the plurality of inverters includes at least two output nodes.

### BRIEF DESCRIPTION OF THE DRAWINGS

FIG. 1 is a circuit diagram of a prior art inverter chain;

FIG. 2 is a layout diagram of the prior art inverter chain shown in FIG. 1;

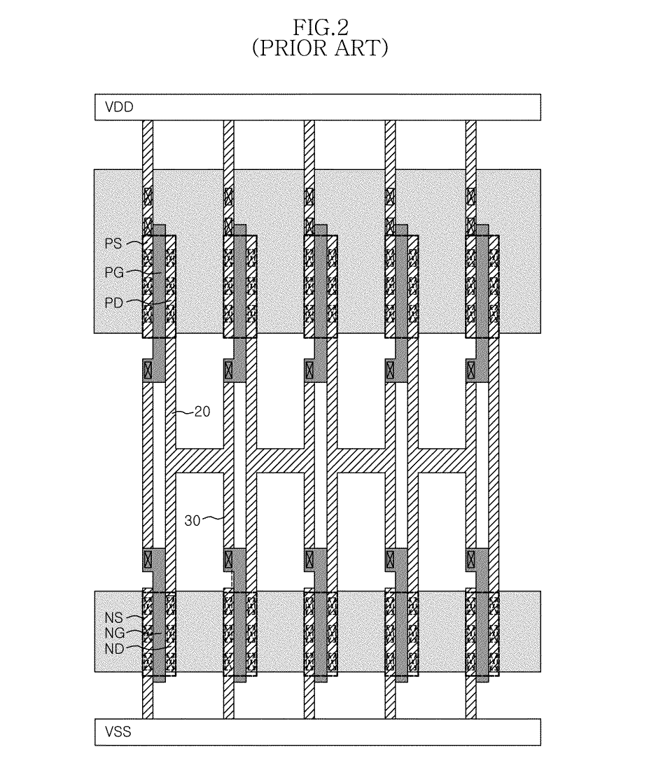

FIG. 3 is a circuit diagram of an embodiment of an inverter chain; and

FIG. 4 is a layout diagram of the embodiment of the inverter chain shown in FIG. 3.

### DETAILED DESCRIPTION

Various embodiments of a semiconductor apparatus will be described below with reference to the accompanying drawings.

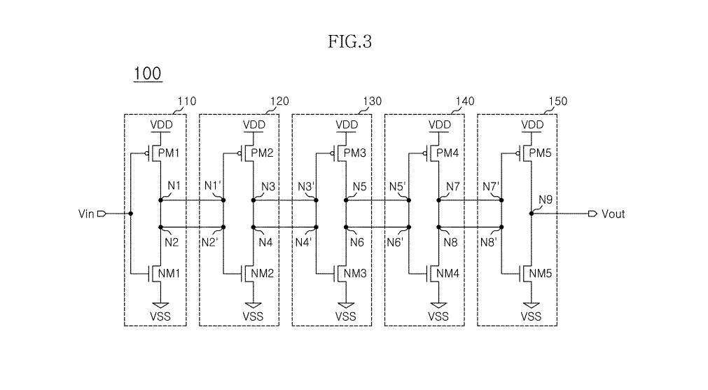

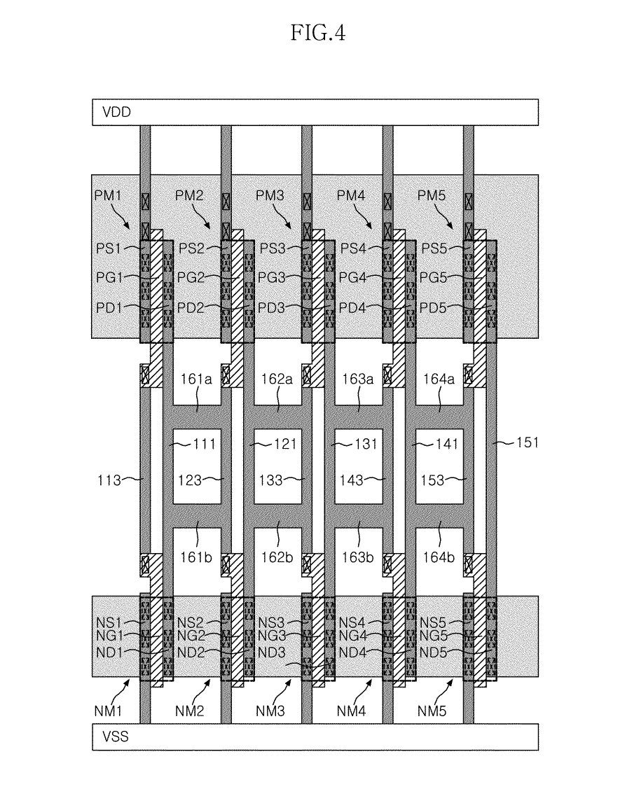

Referring to FIGS. 3 and 4, an inverter chain 100 includes a plurality of inverters 110, 120, 130, 140, 150. The plurality of inverters 110, 120, 130, 140, 150, are electrically coupled in series. In an embodiment, the inverter chain 100 may include five inverters 110, 120, 130, 140, 150. For example, the inverter chain 100 may be configured as an oscillator, where the plurality of inverters 110, 120, 130, 140, 150, are electrically coupled in series.

The first inverter 110 includes a first PMOS transistor PM1 and a first NMOS transistor NM1. The gate terminal PG1 of the first PMOS transistor PM1 is electrically coupled with an input terminal Vin. A source terminal PS1 of the first PMOS transistor PM1 is electrically coupled to the terminal of a power supply voltage VDD. A drain terminal PD1 of the first PMOS transistor PM1 is electrically coupled to a first output node N1. A gate terminal NG1 of the first NMOS transistor NM1 is electrically coupled with the input terminal Vin. A source terminal NS1 of the first NMOS transistor NM1 is electrically coupled to the terminal of a ground voltage VSS. A drain terminal ND1 of the first NMOS transistor NM1 is electrically coupled to a second output node N2.

The second inverter 120 includes a second PMOS transistor PM2 and a second NMOS transistor NM2. The gate terminal PG2 of the second PMOS transistor PM2 is electrically coupled with a first input node N1′. A source terminal PS2 of the second PMOS transistor PM2 is electrically coupled to the terminal of the power supply voltage VDD. A drain terminal PD2 of the second PMOS transistor PM2 is electrically coupled to a third output node N3. A gate terminal NG2 of the second NMOS transistor is electrically coupled with a second input node N2′. A source terminal NS2 of the second NMOS transistor NM2 is electrically coupled to the terminal of the ground voltage VSS. A drain terminal ND2 of the second NMOS transistor NM2 is electrically coupled to a fourth output node N4.

The third inverter 130 includes a third PMOS transistor PM3 and a third NMOS transistor NM3. The gate terminal PG3 of the third PMOS transistor is electrically coupled with a third input node N3′. A source terminal PS3 of the third PMOS transistor PM3 is electrically coupled to the terminal of the power supply voltage VDD. A drain terminal PD3 of the third PMOS transistor PM3 is electrically coupled to a fifth output node N5. A gate terminal NG3 of the third NMOS transistor NM3 is electrically coupled with a fourth input node N4′. A source terminal NS3 of the third NMOS transistor is electrically coupled to the terminal of the ground voltage VSS. A drain terminal ND3 of the third NMOS transistor NM3 is electrically coupled to a sixth output node N6.

The fourth inverter 140 includes a fourth PMOS transistor PM4 and a fourth NMOS transistor NM4. A gate terminal PG4 of the fourth PMOS transistor PM4 is electrically coupled with a fifth input node N5′. A source terminal PS4 of the fourth PMOS transistor PM4 is electrically coupled to the terminal of the power supply voltage VDD. A drain terminal PD4 of the fourth PMOS transistor PM4 is electrically coupled to a seventh output node N7. A gate terminal NG4 of the fourth NMOS transistor NM4 is electrically coupled with a sixth input node N6′. A source terminal NS4 of the fourth NMOS transistor NM4 is electrically coupled to the terminal of the ground voltage VSS. A drain terminal ND4 of the fourth NMOS transistor NM4 is electrically coupled to an eighth output node N8.

The fifth inverter 150 includes a fifth PMOS transistor PM5 and a fifth NMOS transistor NM5. A gate terminal PG5 of the fifth PMOS transistor PM5 is electrically coupled with a seventh input node N7′. A source terminal PS5 of the fifth PMOS transistor PM5 is electrically coupled to the terminal of the power supply voltage VDD. A drain terminal PD5 of the fifth PMOS transistor PM5 is electrically coupled to an output terminal Vout. A gate terminal NG5 of the fifth NMOS transistor NM5 is electrically coupled with an eighth input node N8′. A source terminal NS5 of the fifth NMOS transistor NM5 is electrically coupled to the terminal of the ground voltage VSS. A drain terminal ND5 of the fifth NMOS transistor NM5 is electrically coupled to the output terminal Vout.

A mentioned above, an inverter chain 100 includes a plurality of inverters 110, 120, 130, 140, 150. In the embodiment, one or more of the plurality of inverters 110, 120, 130, 140, 150, such as for example, the first, second, third and fourth inverters 110, 120, 130, 140 have a plurality of output nodes N1, N2, N3, N4, N5, N6, N7, N8.

More specifically, the first, second, third and fourth inverters 110, 120, 130, 140 include the first, second, third and fourth PMOS transistors PM1, PM2, PM3, PM4 and the first, second, third and fourth NMOS transistors NM1, NM2, NM3, NM4, respectively. The first inverter 110 includes two output nodes N1, N2. The second inverter 120 includes two output nodes N3, N4. The third inverter 130 includes two output nodes N5, N6. The fourth inverter includes two output nodes N7, N8. The plurality of output nodes N1, N2, N3, N4, N5, N6, N7, N8 of the first, second, third and fourth inverters 110, 120, 130, 140 may be formed via a plurality of electrical coupling lines.

The drain wiring lines 111, 121, 131, 141 electrically couple the drain terminals of the PMOS transistors PM1, PM2, PM3, PM4 to the drain terminals of the NMOS transistors NM1, NM2, NM3, NM4. More specifically, drain wiring line 111 electrically couples the drain terminal PD1 with the drain terminal ND1. The drain wiring 121 electrically couples the drain terminal PD2 with the drain terminal ND2. The drain wiring 131 electrically couples the drain terminal PD3 with the drain terminal ND3. The drain wiring 141 electrically couples the drain terminal PD4 with the drain terminal ND4.

The gate wiring lines 123, 133, 143, 153 electrically couple the gate terminals of the gate terminals of the PMOS transistors PM2, PM3, PM4, PM5 to the gate terminals of the NMOS transistors NM2, NM3, NM4, NM5. More specifically, gate wiring line 123 electrically couples the gate terminal PG2 with the gate terminal NG2. The gate wiring line 133 electrically couples the gate terminal PG3 with the gate terminal NG3. The gate wiring line 143 electrically couples the gate terminal PG4 with the gate terminal NG4. The gate wiring line 153 electrically couples the gate terminal PG5 with the gate terminal NG5.

First electrical coupling lines 161a, 162a, 163a, 164a electrically couple the drain wiring lines 111, 121, 131, 141 of each of the respective inverters 110, 120, 130, 140 at positions adjacent to the drain terminals PD1, PD2, PD3, PD4 of the PMOS transistors PM1, PM2, PM3, PM4. More specifically, the first electrical coupling line 161a is electrically coupled to the drain wiring line 111 at a position adjacent the drain terminal PD1 of the PMOS transistor PM1. The second electrical coupling line 162a is electrically coupled to the drain wiring line 121 at a position adjacent the drain terminal PD2 of the PMOS transistor PM2. The third electrical coupling line 163a is electrically coupled to the drain wiring line 131 at a position adjacent the drain terminal PD3 of the PMOS transistor PM3. The fourth electrical coupling line 164a is electrically coupled to the drain wiring line 141 at a position adjacent the drain terminal PD4 of the PMOS transistor PM4.

Second electrical coupling lines 161b, 162b, 163b, 164b electrically couple the drain wiring lines 111, 121, 131, 141 each of the respective inverters 110, 120, 130, 140 at positions adjacent to the drain terminals ND1, ND2, ND3, ND4 of the NMOS transistors NM1, NM2, NM3, NM4. More specifically, the second electrical coupling line 161b is electrically coupled to the drain wiring line 111 at a position adjacent the drain terminal ND1 of the NMOS transistor NM1. The second electrical coupling line 162b is electrically coupled to the drain wiring line 121 at a position adjacent the drain terminal ND2 of the NMOS transistor NM2. The third electrical coupling line 163b is electrically coupled to the drain wiring line 131 at a position adjacent the drain terminal ND3 of the NMOS transistor NM3. The fourth electrical coupling line 164b is electrically coupled to the drain wiring line 141 at a position adjacent the drain terminal ND4 of the NMOS transistor NM4.

The positions adjacent to the drain terminals PD1, PD2, PD3, PD4 of the PMOS transistors PM1, PM2, PM3, PM4 refer to positions that are adjacent to and relatively closer to the drain terminals PD1, PD2, PD3, PD4 of the PMOS transistors PM1, PM2, PM3, PM4 than to the midway position on the drain wiring lines 111, 121, 131, 141.

The positions adjacent to the drain terminals ND1, ND2, ND3, ND4 of the NMOS transistors NM1, NM2, NM3, NM4 refer to positions that are adjacent to and relatively closer to the drain terminals ND1, ND2, ND3, ND4 of the NMOS transistors NM1, NM2, NM3, NM4 than to the midway position on the drain wiring lines 111, 121, 131, 141.

In an embodiment, the plurality of output nodes N1, N2, N3, N4, N5, N6, N7, N8 may be formed in a subset of the plurality of inverters 110, 120, 130, 140, 150. An example of a subset of the plurality of inverters includes the first, second, third and fourth inverters 110, 120, 130, 140 of the plurality of inverters. The first, second, third, fourth, fifth, sixth, seventh and eighth input nodes N1′, N2′, N3′, N4′, N5′, N6′, N7′, N8′ of the second, third, fourth and fifth inverters, 120, 130, 140, 150 are electrically coupled to the first, second, third, fourth, fifth, sixth, seventh and eighth output nodes N1, N2, N3, N4, N5, N6, N7, N8 of the first, second, third and fourth inverters, 110, 120, 130, 140, respectively.

While various embodiments may use electrical coupling lines that include the first and second electrical coupling lines, alternative embodiments may use a greater number of electrical coupling lines.

Operations of an embodiment of an inverter chain will be described below.

When a low level potential is supplied to the input terminal of the first inverter 110, the first PMOS transistor PM1 in the first inverter 110 is turned on, the second NMOS transistor NM2 in the second inverter 120 is turned on, the third PMOS transistor PM3 in the third inverter 130 is turned on, the fourth NMOS transistor NM4 in the fourth inverter 140 is turned on, and the fifth PMOS transistor PM5 in the fifth inverter 150 is turned on and a high level potential may be generated as an output.

A first rising path is formed such that the current associated with the power supply voltage VDD flows from the drain wiring line 111 of the first inverter 110 to the gate wiring line 123 of the second inverter 120 via the first electrical coupling line 161a.

A first falling path is formed such that the current associated with the ground voltage VSS flows from the drain wiring line 121 of the second inverter 120 to the gate wiring line 133 of the third inverter 130 via the second electrical coupling line 162b.

A second rising path is formed such that the current associated with the power supply voltage VDD flows from the drain wiring line 131 of the third inverter 130 to the gate wiring line 143 of the fourth inverter 140 via the first electrical coupling line 163a.

A second falling path is formed such that the current associated with the ground voltage VSS flows from the drain wiring line 141 of the fourth inverter 140 to the gate wiring line 153 of the fifth inverter 150 via the second electrical coupling line 164b.

Since each one of the first electrical coupling lines 161a, 162a, 163a, 164a are electrically coupled to the respective one of the drain wiring lines 111, 121, 131, 141 at positions adjacent to the drain terminals PD1, PD2, PD3, PD4 of the PMOS transistors PM1, PM2, PM3 and PM4, the distance of a rising path may be shortened. The relatively shorter distance of the rising path may result in relative shortening of a rising time of the inverter chain.

Since Each one of the second electrical coupling lines 161b, 162b, 163b, 164b are electrically coupled to the respective one of the drain wiring lines 111, 121, 131, 141 at positions adjacent to the drain terminals ND1, ND2, ND3, ND4 of the NMOS transistors NM1, NM2, NM3, NM4, the distance of a falling path may be shortened. The relatively shorter distance of the falling path may result in relative shortening of a falling time of the inverter chain.

In an embodiment, efficiencies associated with the rising time and the falling time of an inverter may be enhanced through an improvement of a rising path and a falling path.

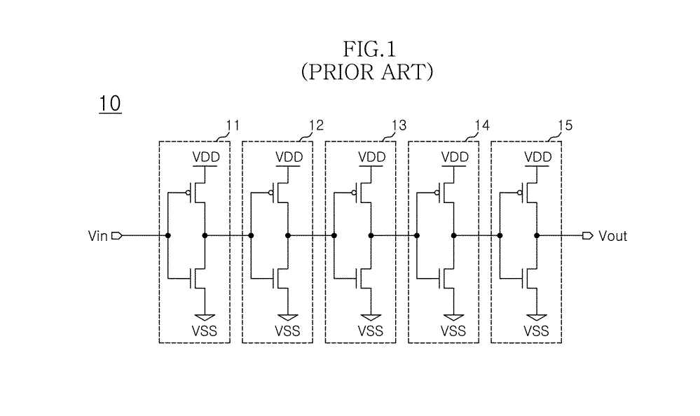

Referring to FIG. 5, a block diagram representation of a system 1000 including an embodiment of a semiconductor device 1350 is shown. In an embodiment, the semiconductor device 1350 is the semiconductor device including the delay circuit of FIG. 1. The system 1000 includes one or more semiconductor memory devices 1350 and a memory controller 1200

In an embodiment, the semiconductor device 1350 is a semiconductor memory device. In an embodiment, a system includes a memory controller and a semiconductor memory device including an inverter chain including a plurality of inverters, wherein the plurality of inverters are electrically coupled in series, and at least one of the plurality of inverters includes at least two output nodes.

Examples of the semiconductor memory device 1350 include, but are not limited to, dynamic random access memory, static random access memory, synchronous dynamic random access memory (SDRAM), synchronous graphics random access memory (SGRAM), double data rate dynamic ram (DDR), and double data rate SDRAM.

The memory controller 1200 is used in the design of memory devices, processors, and computer systems. The system 1000 may include one or more processors or central processing units (“CPUs”) 1100. The CPU 1100 may be used individually or in combination with other CPUs. While the CPU 1100 will be referred to primarily in the singular, it will be understood by those skilled in the art that a system with any number of physical or logical CPUs may be implemented

A chipset 1150 may be electrically coupled to the CPU 1100. The chipset 1150 is a communication pathway for signals between the CPU 1100 and other components of the system 1000, which may include the memory controller 1200, an input/output (“I/O”) bus 1250, and a disk drive controller 1300. Depending on the configuration of the system 1000, any one of a number of different signals may be transmitted through the chipset 1150, and those skilled in the art will appreciate that the routing of the signals throughout the system 1000 can be readily adjusted without changing the underlying nature of the system.

As stated above, the memory controller 1200 may be electrically coupled to the chipset 1150. The memory controller 1200 can receive a request provided from the CPU 1100, through the chipset 1150. In alternate embodiments, the memory controller 1200 may be integrated into the chipset 1150. The memory controller 1200 may be electrically coupled to one or more memory devices 1350. The memory devices 1350 may be any one of a number of industry standard memory types, including but not limited to, single inline memory modules (“SIMMs”) and dual inline memory modules (“DIMMs”). Further, the memory devices 1350 may facilitate the safe removal of the external data storage devices by storing both instructions and data.

The chipset 1150 may be electrically coupled to the I/O bus 1250. The I/O bus 1250 may serve as a communication pathway for signals from the chipset 1150 to I/O devices 1410, 1420 and 1430. The I/O devices 1410, 1420 and 1430 may include a mouse 1410, a video display 1420, or a keyboard 1430. The I/O bus 1250 may employ any one of a number of communications protocols to communicate with the I/O devices 1410, 1420, and 1430. Further, the I/O bus 1250 may be integrated into the chipset 1150.

The disk drive controller 1450 may also be electrically coupled to the chipset 1150. The disk drive controller 1450 may serve as the communication pathway between the chipset 1150 and one or more internal disk drives 1450. The internal disk drive 1450 may facilitate disconnection of the external data storage devices by storing both instructions and data. The disk drive controller 1300 and the internal disk drives 1450 may communicate with each other or with the chipset 1150 using virtually any type of communication protocol, including all of those mentioned above with regard to the I/O bus 1250.

The system 1000 described above in relation to FIG. 5 is merely one example of a system employing a semiconductor memory device 1350. In alternate embodiments, such as cellular phones or digital cameras, the components may differ from the embodiment shown in FIG. 5.

While certain embodiments have been described above, it will be understood to those skilled in the art that the embodiments described are by way of example only. Accordingly, the semiconductor apparatus described herein should not be limited based on the described embodiments. Rather, the semiconductor apparatus described herein should only be limited in light of the claims that follow when taken in conjunction with the above description and accompanying drawings.

What is claimed is:

1. A semiconductor apparatus comprising:
an inverter chain including a plurality of inverters, wherein the plurality of inverters are electrically coupled in series, and at least one of the plurality of inverters includes at least two output nodes.

2. The semiconductor apparatus according to claim 1, wherein each of the plurality of output nodes comprise an associated one of a plurality of electrical coupling lines wherein each of the electrical coupling lines electrically couple an output of a first inverter of the plurality of inverters with an input of a second one of the plurality of inverters.

3. The semiconductor apparatus according to claim 1,
wherein each one of the plurality of inverters comprises:
a PMOS transistor;
an NMOS transistor; and
a drain wiring line, wherein the drain wiring line electrically couples a drain terminal of the PMOS transistor with a drain terminal of the NMOS transistor.

4. The semiconductor apparatus according to claim 3, wherein the drain wiring line has a midway point and each one of the plurality of inverters further comprises:
a first electrical coupling line electrically coupled to the drain wiring line at a position adjacent to the PMOS transistor and relatively closer to the PMOS transistor than to the midway point of the drain wiring line; and
a second electrical coupling line electrically coupled to the drain wiring line at a position adjacent to the NMOS transistor and relatively closer to the NMOS transistor than to the midway point of the drain wiring line.

5. The semiconductor apparatus of claim 4, wherein a first one of the at least two output nodes comprises a first node where the first electrical coupling line is electrically coupled to the drain wiring line and a second one of the output nodes comprise a second node where the second electrical coupling line is electrically coupled to the drain wiring line.

6. The semiconductor apparatus of claim 4, wherein second inverter comprises a gate wiring line electrically coupling a gate terminal of the PMOS transistor of the second inverter with a gate terminal of the NMOS transistor of the second inverter.

7. The semiconductor apparatus of claim 6, wherein a first electrical coupling line electrically coupled to a drain wiring line of a first one of the plurality of inverters is electrically coupled to a gate wiring line of a second one of the plurality of inverters and a second electrical coupling line electrically coupled to the drain wiring line of the first one of the plurality of inverters is electrically coupled to the gate wiring line of the second one of the plurality of inverters.

8. The semiconductor apparatus according to claim 1, wherein the inverter chain comprises an oscillator.

9. A semiconductor apparatus comprising:
an inverter chain including a plurality of inverters, wherein the plurality of inverters are electrically coupled in series,
wherein the plurality of inverters consists of a final inverter and a first subset of inverters, wherein each of the first subset of inverters includes at least two output nodes, and
wherein the plurality of inverters consists of a first inverter and a second subset of inverters, wherein the second subset of inverters includes the final inverter and the first subset of inverters includes the first inverter and wherein each of the second subset of inverters includes at least two input nodes.

10. The semiconductor apparatus according to claim 9, wherein each of the at least two output nodes of one of the plurality of inverters is electrically coupled with a corresponding one of the at least two input nodes of a second one of the plurality of inverters via an associated electrical coupling line.

11. The semiconductor apparatus according to claim 10, wherein the electrical coupling lines associated with a first one of the plurality of inverters comprises a first electrical coupling line configured to transmit a rising signal of generated by the first one of the plurality of inverters and a second electrical coupling line configured to transmit a falling signal generated by the first one of the plurality of inverters.
